(19) United States
(12) Patent Application Publication
(10) Pub. No.: US 2024/0153871 A1
(43) Pub. Date: May 9, 2024

(54) SUBSTRATE INTEGRATED WITH PASSIVE DEVICES AND MANUFACTURING METHOD THEREOF

(71) Applicant: BOE TECHNOLOGY GROUP CO., LTD., Beijing (CN)

(72) Inventors: Zhanfeng CAO, Beijing (CN); Jin YANG, Beijing (CN); Yingwei LIU, Beijing (CN); Ke WANG, Beijing (CN); Haixu LI, Beijing (CN)

(21) Appl. No.: 17/773,106

(22) PCT Filed: Apr. 23, 2021
(86) PCT No.: PCT/CN2021/089230

§ 371 Date: Oct. 27, 2022

(51) Int. Cl. H01L 23/522; H01F 41/04

(52) U.S. Cl. CPC H01L 23/5227; H01F 41/04; H01L 23/5222; H01L 23/5226

(57) ABSTRACT

A substrate integrated with passive devices and a manufacturing method thereof are provided. The manufacturing method of the substrate integrated with passive devices includes: integrating the passive devices on a transparent dielectric layer; forming the passive devices includes at least forming an inductor, wherein the inductor includes first sub-structures on a first surface thereof and second sub-structures on a second surface thereof, and first connection electrodes in first connection vias, respectively, to sequentially connect the first sub-structures and the second sub-structures together; forming the inductor includes: forming a first metal film layer on the first surface and/or the second surface, and forming the first connection electrodes in the first connection vias through an electroplating process, to fill the first connection vias; and forming a pattern including the first sub-structures on the first surface and a pattern including the second sub-structures on the second surface, through patterning processes, respectively.

### CROSS-REFERENCE TO RELATED APPLICATIONS

This is a National Phase Application filed under 35 U.S.C. 371 as a national stage of PCT/CN2021/089230 filed on Apr. 23, 2021, the content of which is incorporated herein by reference in its entirety.

### TECHNICAL FIELD

The present disclosure belongs to the technical field of radio frequency devices, and particularly relates to a substrate integrated with passive devices and a manufacturing method thereof.

### BACKGROUND

Nowadays, the consumer electronics industry is developing day by day. Mobile communication terminals represented by mobile phones, especially 5G mobile phones, are developing rapidly. The frequency bands of signals to be processed by the mobile phones are increasing, and the number of RF (radio frequency) chips required is also increasing. The mobile phone form enjoyed by consumers is developing continuously towards miniaturization, lightness and thinness and long power-supply durability per charging cycle. In traditional mobile phones, a large number of discrete components such as resistors, capacitors, inductors, filters, and the like exist on the RF PCB board. The discrete components have the disadvantages of large volume, high power consumption, multiple welding spots and large parasitic parameter change, making it difficult to meet future requirements. The interconnection, matching and the like between RF chips require an integrated passive device with small area, high performance and good consistency. The integrated passive devices currently available on the market are mainly based on Si (silicon) substrates and GaAs (gallium arsenide) substrates. A Si-based integrated passive device has the advantage of low price, but Si itself has trace impurities (poor insulation), which leads to high microwave loss and average performance of the device; a GaAs-based integrated passive device has the advantage of excellent performance, but is expensive.

### SUMMARY

Some embodiments of the present disclosure provide a substrate integrated with passive devices and a manufacturing method thereof.

An embodiment of the present disclosure provides a manufacturing method of a substrate integrated with passive devices, including:
providing a transparent dielectric layer, wherein the transparent dielectric layer includes a first surface and a second surface which are opposite to each other along a thickness direction of the transparent dielectric layer; and the transparent dielectric layer has first connection vias which penetrate through the transparent dielectric layer along the thickness direction of the transparent dielectric layer;
integrating the passive devices on the transparent dielectric layer, wherein forming the passive devices includes at least forming an inductor; the inductor includes first sub-structures on the first surface and second sub-structures on the second surface, and first connection electrodes in the first connection vias, respectively, to sequentially connect the first sub-structures and the second sub-structures together; wherein
the forming the inductor includes:
forming a first metal film layer on the first surface and/or the second surface of the transparent dielectric layer, and forming the first connection electrodes in the first connection vias through an electroplating process; the first connection electrodes filling the first connection vias; and
forming a pattern including the first sub-structures on the first surface of the transparent dielectric layer through a patterning process, and forming a pattern including the second sub-structures on the second surface of the transparent dielectric layer through a patterning process.

The forming the inductor includes:
forming the first metal film layer on the second surface of the transparent dielectric layer, forming a first metal material in the first connection vias through a patterning process, and forming the first connection electrodes in the first connection vias through an electroplating process.

Prior to forming the first metal film layer on the second surface of the transparent dielectric layer, the manufacturing method further includes:
forming an auxiliary metal film layer on the second surface of the transparent dielectric layer to increase an adhesive force between the first metal film layer and the second surface of the transparent dielectric layer.

The providing the transparent dielectric layer includes:
providing a substrate, and coating a first adhesive layer on the substrate; and attaching the first surface of the transparent dielectric layer to the first adhesive layer.

A material of the first adhesive layer includes a temperature-controlled adhesive.

The forming the inductor includes:
providing a substrate, and coating a first adhesive layer on the substrate;
forming a first metal film layer on the first adhesive layer;
forming a second adhesive layer on a side of the first metal film layer distal to the first adhesive layer, patterning the second adhesive layer to remove portions of the second adhesive layer corresponding to positions of the first connection vias in the transparent dielectric layer to be attached to the second adhesive layer; and
attaching the first surface of the transparent dielectric layer to the second adhesive layer, and forming the first connection electrodes in the first connection vias through an electroplating process.

Prior to forming the first metal film layer on the first adhesive layer, the manufacturing method includes:
forming an auxiliary metal film layer on the first adhesive layer to increase an adhesive force between the first metal film layer and the first adhesive layer.

The passive devices further include a capacitor, and the manufacturing method further includes:
forming a first plate of the capacitor while forming the second sub-structures of the inductor;
forming a first interlayer dielectric layer on a side, which is distal to the transparent dielectric layer, of a layer where the second sub-structures of the inductor and the first plate of the capacitor are located; and
forming a second plate of the capacitor on a side of the first interlayer dielectric layer distal to the transparent dielectric layer.

The inductor includes a first lead terminal connected to a first connection pad and a second lead terminal connected to a second end of the first plate of the capacitor; the second plate of the capacitor is connected to a second connection pad; the manufacturing method further includes:
forming a second interlayer dielectric layer on a side, which is distal to the first interlayer dielectric layer, of a layer where the second plate of the capacitor and the second connection pad are located;
forming a second connection via and a third connection via which penetrate through the second interlayer dielectric layer; and
forming the first connection pad and the second connection pad; wherein the first connection pad is connected to the first lead terminal through the second connection via; and the second connection pad is connected to the second plate of the capacitor through the third connection via.

The transparent dielectric layer includes a glass substrate.

An embodiment of the present disclosure provides a substrate integrated with passive devices, including a transparent dielectric layer and the passive devices integrated on the dielectric layer; wherein
the transparent dielectric layer includes a first surface and a second surface which are opposite to each other along a thickness direction of the transparent dielectric layer; and the transparent dielectric layer has first connection vias which penetrate through the transparent dielectric layer along the thickness direction of the transparent dielectric layer;
the passive devices include at least an inductor; the inductor includes first sub-structures on the first surface and second sub-structures on the second surface, and first connection electrodes in the first connection vias, respectively, to sequentially connect the first sub-structures and the second sub-structures together.

The passive devices further include a capacitor; the capacitor includes a first plate which is in the same layer as the second sub-structures of the inductor; the substrate further includes a first interlayer dielectric layer on a side, which is distal to the transparent dielectric layer, of the first plate of the capacitor; and the capacitor includes a second plate on a side, which is distal to the first plate of the capacitor, of the first interlayer dielectric layer.

The transparent dielectric layer includes a glass substrate.

### BRIEF DESCRIPTION OF DRAWINGS

FIG. 1 is a top view of an inductor according to an embodiment of the present disclosure.

FIG. 2 is a perspective view of an LC oscillating circuit (or LC oscillator circuit) according to an embodiment of the present disclosure.

FIG. 3 is a top view of a glass substrate according to an embodiment of the present disclosure.

FIG. 4 is a schematic view of a substrate integrated with passive devices according to an embodiment of the present disclosure.

FIG. 5a is a schematic diagram of a substrate formed in step S11 according to an embodiment of the present disclosure.

FIG. 5b is a schematic diagram of a substrate formed in step S12 according to an embodiment of the present disclosure.

FIG. 5c is a schematic diagram of a substrate formed in step S13 according to an embodiment of the present disclosure.

FIG. 5d is a schematic diagram of a substrate formed in step S14 according to an embodiment of the present disclosure.

FIG. 5e is a schematic diagram of a substrate formed in step S15 according to an embodiment of the present disclosure.

FIG. 5f is a schematic diagram of a substrate formed in step S16 according to an embodiment of the present disclosure.

FIG. 5g is a schematic diagram of a substrate formed in step S17 according to an embodiment of the present disclosure.

FIG. 6a is a schematic diagram of a substrate formed in step S23 according to an embodiment of the present disclosure.

FIG. 6b is a schematic diagram of a substrate formed in step S24 according to an embodiment of the present disclosure.

FIG. 6c is a schematic diagram of a substrate formed in step S25 according to an embodiment of the present disclosure.

FIG. 6d is a schematic diagram of a substrate formed in step S26 according to an embodiment of the present disclosure.

FIG. 6e is a schematic diagram of a substrate formed in step S27 according to an embodiment of the present disclosure.

### DETAIL DESCRIPTION OF EMBODIMENTS

In order enable one of ordinary skill in the art to better understand the technical solutions of the present disclosure, the present disclosure will be further described below in detail with reference to the accompanying drawings and exemplary embodiments.

Unless defined otherwise, technical or scientific terms used herein shall have the ordinary meaning as understood by one of ordinary skill in the art to which the present disclosure belongs. The words “first”, “second”, and the like used in the present disclosure do not denote any order, quantity, or importance, but rather distinguish one element from another. Likewise, the words “a”, “an”, or “the” and the like do not denote a limitation of quantity, but rather denote the presence of at least one element. The word “comprising”, “including”, or the like, means that the element or item preceding the word contains the element or item listed after the word and its equivalent, but does not exclude other elements or items. The term “connected”, “coupled”, or the like is not restricted to physical or mechanical connections, but may include electrical connections, whether direct or indirect connections. “Upper”, “lower”, “left”, “right”, and the like are used only to indicate relative positional relationships, and when the absolute position of the object being described is changed, the relative positional relationships may also be changed accordingly.

An embodiment of the present disclosure provides a manufacturing method of (or a method for manufacturing) a substrate integrated with passive devices, and a position relation between film layers and material selection of each film layer of the substrate integrated with passive devices.

At present, passive devices such as capacitors, inductors, resistors, etc. are integrated on a substrate to form a circuit structure. In the embodiments of the present disclosure, as an example, an LC oscillating circuit is integrated on a substrate. That is, at least inductive and capacitive devices are integrated on the substrate. It should be understood that devices such as resistors may also be integrated on the substrate depending on the function and performance of the circuit.

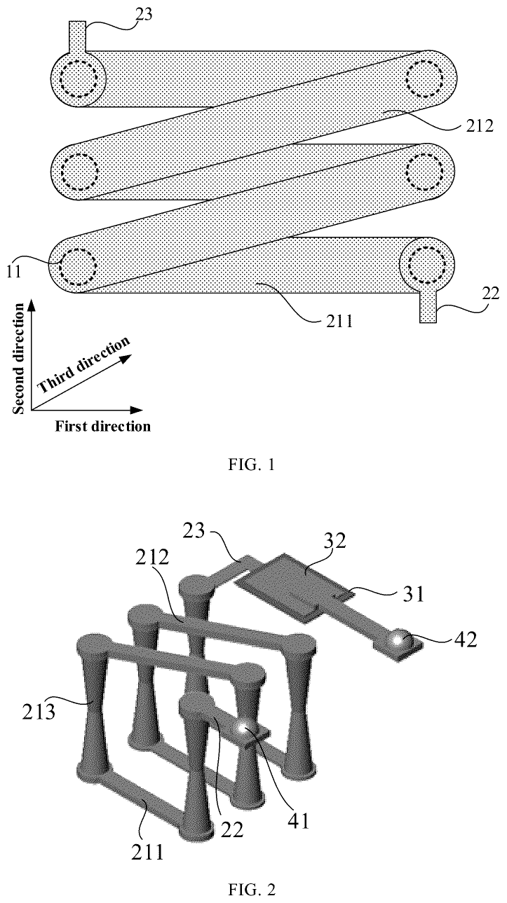

FIG. 1 is a top view of an inductor according to an embodiment of the present disclosure. Referring to FIG. 1, each of first sub-structures 211 of the inductor extends along a first direction and is arranged side by side along a second direction; each of second sub-structures 212 of the inductor extends along a third direction and is arranged side by side along the second direction. The first direction, the second direction, and the third direction are all different directions, respectively. In the embodiment of the present disclosure, as an example, the first direction and the second direction are perpendicular to each other, and the first direction and the third direction intersect and are non-perpendicular to each other. Alternatively, the extending directions of the first sub-structure 211 and the second sub-structure 212 may be interchanged, which is also within the protection scope of the embodiments of the present disclosure. In addition, in the embodiment of the present disclosure, the inductor includes N first sub-structures 211 and N−1 second sub-structures 212 as an example for description, where N is greater than or equal to 2, and N is an integer. Orthogonal projections of each of a first end and a second end of each first sub-structure 211 on a glass substrate 10 at least partially overlap with an orthogonal projection of one first connection via 11 on the glass substrate 10. Further, the first end and the second end of one first sub-structure 211 correspond to different first connection vias 11, i.e. an orthogonal projection of one first sub-structure 211 on the glass substrate 10 at least partially overlaps orthogonal projections of two first connection vias 11 on the glass substrate 10. In this case, the first end and the second end of an i-th second sub-structure 212 of the inductor are respectively connected to the first end of an i-th first sub-structure 211 and the second end of an (i+1)th first sub-structure 211, to form an inductor coil, where i is greater than or equal to 1 and less than or equal to N−1 (i.e., 1≤i≤N−1), and i is an integer.

It should be noted that, a first lead terminal 22 is connected to the second end of a first one of the first sub-structures 211 of the inductor coil, and a second lead terminal 23 is connected to the first end of the N-th first sub-structure 211. Further, the first lead terminal 22 and the second lead terminal 23 may be disposed in the same layer as the second sub-structures 212 and made of the same material. It this case, the first lead terminal 22 may be connected to the second end of first one of the first sub-structures 211 through the first connection via 11, and correspondingly, the second lead terminal 23 may be connected to the first end of the N-th first sub-structure 211 through the first connection via 11.

FIG. 2 is a schematic perspective view of an LC oscillating circuit according to an embodiment of the present disclosure. As shown in FIG. 2, the LC oscillating circuit includes an inductor and a capacitor 3; wherein the inductor includes a plurality of first sub-structures 211, a plurality of second sub-structures 212, and a plurality of first connection electrodes 213; each first sub-structure 211 and a corresponding second sub-structure 212 are disposed at opposite ends of a corresponding first connection electrode 213, and each first sub-structures 211 and the corresponding second sub-structures 212 are connected to each other through the corresponding first connection electrode 213, forming a three-dimensional inductor coil. With continued reference to FIG. 2, the first lead terminal 22 of the inductor coil is connected to a first connection pad 41, the second lead terminal 23 of the inductor coil is connected to a first plate 31 of the capacitor 3, a second plate 32 of the capacitor 3 is connected to a second connection pad 42, and the first connection pad 41 and the second connection pad 42 are connected to the positive and negative poles of a current source or a voltage source, respectively.

FIG. 4 is a schematic view of a substrate integrated with passive devices according to an embodiment of the present disclosure. As shown in FIG. 4, in the embodiment of the present disclosure, the LC oscillating circuit is integrated on a transparent dielectric layer, which includes a first surface and a second surface oppositely arranged along a thickness direction thereof, and has first connection vias 11 penetrating through the transparent dielectric layer along the thickness direction of the transparent dielectric layer. The first connection electrodes 213 of the inductor coil are formed in the first connection vias 11, respectively, the first sub-structures 211 of the inductor coil are formed on the first surface of the transparent dielectric layer, and the second sub-structures 212 of the inductor coil are formed on the second surface of the transparent dielectric layer. The first plate 31 of the capacitor 3 is connected to a second sub-structure and is arranged in the same layer as the second sub-structure. A first interlayer dielectric layer 5 and the second plate 32 of the capacitor 3 are sequentially arranged on a side of the first plate 31 of the capacitor 3 away from (or distal to) the transparent dielectric layer. A second interlayer dielectric layer 6 is formed on a side of the second plate 32 of the capacitor 3 away from the transparent dielectric layer, and a second connection via and a third connection via are formed in the second interlayer dielectric layer 6. A first connection pad 41 and a second connection pad 42 are arranged on a side of the second interlayer dielectric layer 6 away from the transparent dielectric layer, the first connection pad 41 is connected to the first lead terminal of the inductor coil through the second connection via; the second connection pad 42 is connected to the second plate 32 of the capacitor 3 through the third connection via.

The transparent dielectric layer in the embodiment of the present disclosure includes, but is not limited to, any one of the glass substrate 10, a flexible substrate, and an interlayer dielectric layer including at least an organic insulating layer. The product, which is obtained by integrating the passive devices on the glass substrate 10, has the advantages of small volume, light weight, high performance, low power consumption, and the like, and the transparent dielectric layer is preferably the glass substrate 10 in the embodiment of the present disclosure. Hereinafter, description will be made by taking an example in which the transparent dielectric layer is the glass substrate 10. In the embodiment of the present disclosure, the glass substrate 10 is specifically TGV glass, and the process for forming the first connection vias 11 in the TGV glass is described below.

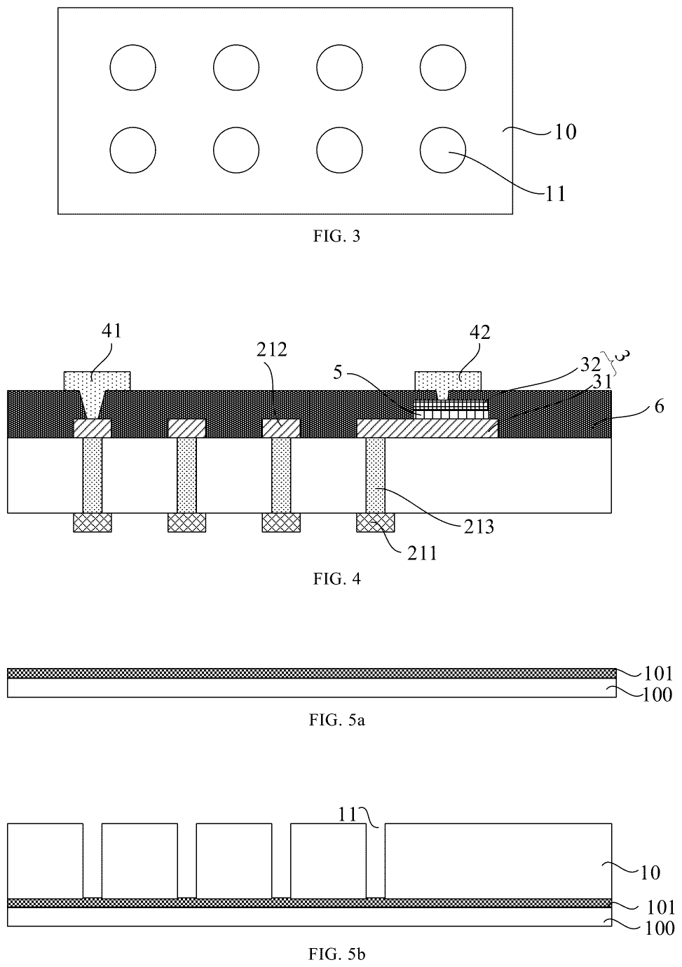

Specifically, FIG. 3 is a top view of a glass substrate 10 according to an embodiment of the present disclosure; as shown in FIG. 3, the step of forming the first connection vias 11 in the glass substrate 10 specifically includes:

(1) Cleaning: the glass substrate 10 may be placed into a cleaning machine for cleaning.

In some examples, the glass substrate 10 has a thickness of about 0.1 mm to 1.1 mm.

(2) Laser drilling: a laser beam emitted from a laser is used to hit the surface of the glass substrate 10 by being perpendicularly incident onto the surface, so as to form a plurality of first connection vias 11 in the glass substrate 10. Specifically, when the laser beam interacts with the glass substrate 10, atoms in the glass substrate 10 are ionized and ejected out of the surface of the glass substrate 10 due to the high energy of the laser photons. As time increases, the punched vias are gradually deepened until penetrating through the entire glass substrate 10, i.e., the plurality of first connection vias 11 are formed. A wavelength of the laser may be 532 nm, 355 nm, 266 nm, 248 nm, 197 nm, etc., a pulse width of the laser may be 1 fs to 100 fs, 1 ps to 100 ps, 1 ns to 100 ns, etc., and the type of the laser may be continuous laser, pulse laser, etc. The method of laser drilling may include, but is not limited to, the following two methods. In the first method, when the diameter of a light spot is large, the relative position of the laser beam and the glass substrate 10 is fixed, the glass substrate 10 is directly punched through by high energy, the shape of each of the first connection vias 11 formed at the moment is an inverted circular truncated cone, and the diameter of the inverted circular truncated cone is sequentially reduced from top to bottom (from the second surface to the first surface). In the second method, when the diameter of a light spot is small, the laser beam draws a circle on the glass substrate 10 for scanning, the focus point of the light spot is constantly changed, the depth of the focus point is constantly changed, a spiral line is drawn from the lower surface (first surface) of the glass substrate 10 to the upper surface (second surface) of the glass substrate 10, the radius of the spiral line is sequentially reduced from bottom to top, a part with a circular truncated cone shape is cut from the glass substrate 10 by the laser and falls down due to the action of gravity, a first connection via 11 is thus formed, and the first connection via is in the shape of a circular truncated cone.

In some examples, each of the first connection vias 11 is formed to have an aperture (or a diameter) of about 10 m to 1 mm.

(3) HF etching: during the process of laser drilling, a stress zone may be formed on the inner wall of each first connection via 11 and in a region of about 5 m to 20 m near the first connection via on the upper surface of the first connection via 11, the surface roughness of the glass substrate 10 in this stress zone shows molten-state burrs, and a large number of micro-cracks and macro-cracks are present, and residual stress is present. At this time, an etching solution containing 2% to 20% of HF is used to carry out a wet etching for a certain time at a proper temperature, the glass in the stress zone is etched away such that the inside of the first connection via 11 and the region near the first connection via on the upper surface of the first connection via 11 are smooth and flat without micro-cracks and macro-cracks, and the stress zone is completely etched away.

In the following, a method for manufacturing a substrate integrated with passive devices according to an embodiment of the present disclosure is specifically described with reference to the accompanying drawings and specific embodiments.

The embodiment of the present disclosure provides a method for manufacturing a substrate integrated with passive devices, including:

Providing a transparent dielectric layer, wherein the transparent dielectric layer includes a first surface and a second surface which are oppositely arranged along a thickness direction of the transparent dielectric layer; and the transparent dielectric layer has first connection vias 11 which penetrate through the transparent dielectric layer along the thickness direction of the transparent dielectric layer; and

Integrating the passive devices on the transparent dielectric layer, wherein forming the passive devices includes at least forming an inductor; the inductor includes first sub-structures 211 formed on the first surface and second sub-structures 212 formed on the second surface, and first connection electrodes 213 respectively formed in the first connection vias 11 to sequentially connect the first sub-structures 211 and the second sub-structures 212 to each other; wherein, the forming the inductor includes:

Forming a first metal film layer on the first surface and/or the second surface of the transparent dielectric layer, and forming the first connection electrodes 213 in the first connection vias 11, respectively, through an electroplating process; the first connection electrodes 213 filling the first connection vias 11, respectively; and

Forming a pattern including the first sub-structures 211 on the first surface of the transparent dielectric layer, and forming a pattern including the second sub-structures 212 on the second surface of the transparent dielectric layer, through patterning processes, respectively.

In the following, the method for manufacturing a substrate integrated with passive devices according to the embodiments of the present disclosure is further described with reference to specific examples.

A first example is a method for manufacturing a substrate integrated with passive devices, specifically including the following steps:

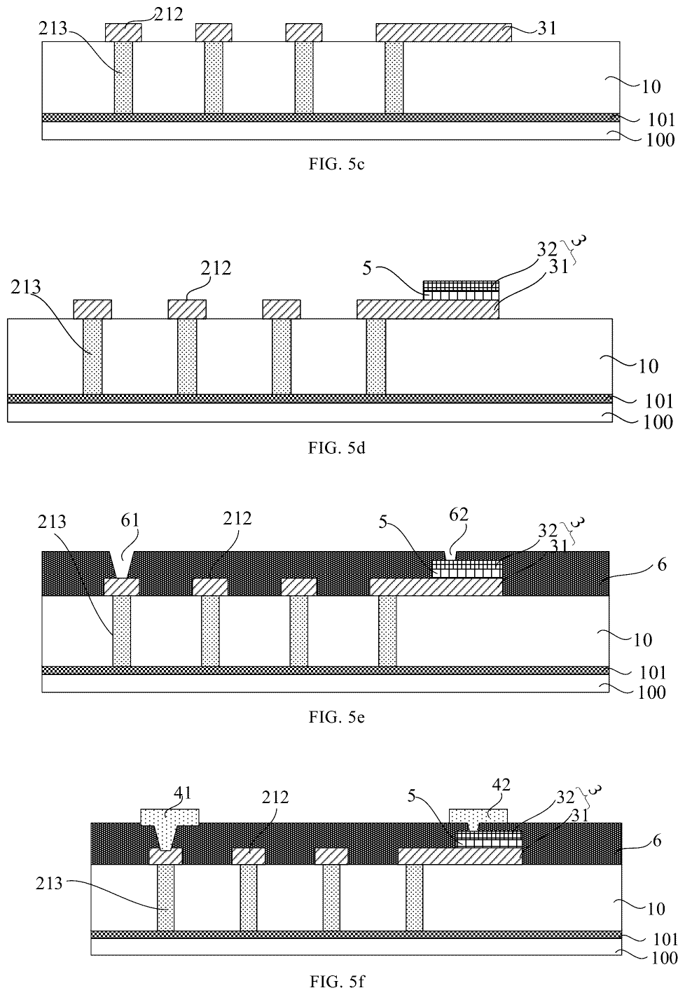

Step S11, providing a substrate 100, and coating a first adhesive layer 101 on the substrate 100, as shown in FIG. 5a.

The material of the first adhesive layer 101 includes, but is not limited to, a temperature-controlled adhesive, for example, an OCA adhesive.

Step S12, attaching the first surface of the glass substrate 10 having the first connection vias 11 to the first adhesive layer, as shown in FIG. 5b.

Step S13, forming a first metal film layer on the second surface of the glass substrate 10, and forming the first connection electrodes 213 in the first connection vias 11, respectively, through an electroplating process, as shown in FIG. 5c.

In some examples, step S13 may specifically include the following:

(1) Growing a seed layer: depositing a first metal film layer as a plating seed layer on the first surface of the glass substrate 10 by magnetron sputtering, and in this process, the first metal film layer is also deposited on the inner wall of each of the first connection vias 11.

In some examples, the material of the first metal film layer includes, but is not limited to, at least one of copper (Cu), aluminum (Al), molybdenum (Mo), and silver (Ag), and the thickness of the first metal film layer is about 100 nm to 500 nm, and further may be about 50 nm to 35 m. In the following description, for example, the material of the first metal film layer is copper.

In some examples, to increase the adhesion of the first metal film layer to the glass substrate 10, an auxiliary metal film layer may be formed on the second surface of the glass substrate 10 by means including, but not limited to, magnetron sputtering, prior to forming the deposited first metal film layer. A material of the auxiliary metal film layer includes, but is not limited to, at least one of nickel (Ni), molybdenum (Mo) alloy and titanium (Ti) alloy, for example, includes MoNb, and the thickness of the auxiliary metal film layer is about 2 nm to 20 nm.

(2) Electroplating and via-filling: putting the glass substrate 10 on a carrier of an electroplating machine, pressing on the power-on pad, putting the glass substrate into a via-filling electroplating bath (in which there is a special via-filling electrolyte), applying electric current, keeping the electroplating solution continuously and rapidly flowing on the surface of the glass substrate 10, such that cations in the electroplating solution obtain electrons on the inner wall of a first connection via 11 and deposit on the inner wall as atoms, wherein metal copper can be mainly deposited in the first connection via at a high speed (the deposition speed is 0.5 to 3 um/min), while the first surface and the second surface of the glass substrate 10 are flat areas, and the deposition speed of the metal copper on the two surfaces is extremely low (i.e., is 0.005 to 0.05 um/min), through the special via-filling electrolyte of special proportion. As time increases, the metal copper on the inner wall of the first connection via grows gradually thick, and even the first connection via 11 may be completely filled, that is, a corresponding first connection electrode 213 of the inductor coil is formed (that is, the spiral region of the inductor is manufactured). Finally, the glass substrate is taken out and subjected to a deionized water cleaning.

In some examples, step S13 in the embodiments of the present disclosure may include not only (1) and (2) described above but also (3) described below.

(3) Patterning the metal on the second surface: coating photoresist on the metal copper layer on the second surface and, exposing and developing the photoresist, then carrying out a wet etching on the copper, stripping off the photoresist after the etching, thereby the patterning of the metal on the second surface is finished, and the second sub-structures 212 of the inductor coil, the second lead terminal 23 and the first plate 31 of the capacitor 3, which are positioned on the second surface, are formed at this moment. The second lead terminal 23 of the N-th second sub-structure 212 of the inductor coil and the first plate 31 of the capacitor 3 are of an integral structure (i.e., have a one-piece structure).

It should be noted that, step S13 in the embodiment of the present disclosure includes the above (1), (2), and (3) as an example for description.

Step S14, forming a first interlayer dielectric layer 5 and the second plate 32 of the capacitor 3 on the glass substrate 10 formed with the second sub-structures 212 of the inductor coil, the second lead terminal 23 and the first plate 31 of the capacitor 3, as shown in FIG. 5d.

In some examples, step S14 may include sequentially forming the first interlayer dielectric layer 5 and a second metal film layer on the glass substrate 10 formed with the second sub-structures 212 of the inductor coil, the second lead terminal 23, and the first plate 31 of the capacitor 3; then, coating photoresist, exposing and developing the photoresist, and then carrying out a wet etching, stripping off the photoresist after the etching, thereby a pattern including the second plate 32 of the capacitor 3 is formed. Next, the first interlayer dielectric layer 5 may be further patterned to leave only a part of the first interlayer dielectric layer 5 under the second plate 32 of the capacitor 3.

In some examples, the material of the first interlayer dielectric layer 5 is an inorganic insulating material. For example, the first interlayer dielectric layer 5 is an inorganic insulating layer formed of silicon nitride (SiNₓ), or an inorganic insulating layer formed of silicon oxide (SiO₂), or a plurality of stacked composite film layers of a SiNₓ inorganic insulating layer and a SiO₂ inorganic insulating layer. Alternatively, the first interlayer dielectric layer 5 further serves as an interlayer dielectric layer of the capacitor 3.

In some examples, the material of the second metal film layer may be the same as the material of the first metal film layer, and thus is not described herein again.

Step S15, forming a second interlayer dielectric layer 6, and forming a second connection via 61 and a third connection via 62 penetrating through the second interlayer dielectric layer 6, as shown in FIG. 5e. The orthogonal projections of the second connection via 61 and the third connection via 62 on the glass substrate 10 respectively overlap with the orthogonal projections of the first lead terminal 22 and the second plate 32 on the glass substrate 10.

In some examples, the second interlayer dielectric layer 6 may be an inorganic insulating layer formed of silicon nitride (SiNₓ), or an inorganic insulating layer formed of silicon oxide (SiO₂), or a plurality of stacked composite film layers of a SiNₓ inorganic insulating layer and a SiO₂ inorganic insulating layer.

Step S16, forming a first connection pad 41 and a second connection pad 42 on the second interlayer dielectric layer 6, as shown in FIG. 5f; wherein the first connection pad 41 is connected to the first lead terminal 22 of the inductor coil through the second connection via 61; and the second connection pad 42 is connected to the second plate 32 of the storage capacitor 3 through the third connection via 62.

In some examples, the first connection pad 41 and the second connection pad 42 may be specifically solder balls.

Step S17, turning over the glass substrate 10, peeling off the first adhesive layer 101 and the substrate 100, and forming a pattern including the first sub-structures 211 of the inductor coil on the first surface of the glass substrate 10 through a patterning process, as shown in FIG. 5g.

In some examples, step S17 may include depositing a third metal film layer by magnetron sputtering, then, coating photoresist, exposing and developing the photoresist, and then carrying out a wet etching, stripping off the photoresist after the etching, thereby the pattern including the first sub-structures 211 of the inductor coil is formed. The material of the third metal film layer may be the same as that of the first metal film layer, and thus, the description thereof is not repeated.

Thus, passive devices are integrated on the glass substrate 10 to form an LC oscillating circuit.

A second example is a method for manufacturing a substrate integrated with passive devices, specifically including the following steps:

Step S21, providing a substrate 100, and coating a first adhesive layer 101 on the substrate 100.

The material of the first adhesive layer 101 includes, but is not limited to, a temperature-controlled adhesive, for example, an OCA adhesive.

Step S22, forming a first metal film layer on the first adhesive layer 101, forming a second adhesive layer 102 on the first metal film layer, and patterning the second adhesive layer 102 to remove the adhesive material of the second adhesive layer 102 corresponding to the first connection vias 11 in the glass substrate 10.

The material of the second adhesive layer 102 may be the same as that of the first adhesive layer 101; that is, the material of the second adhesive layer 102 may also be the OCA adhesive. The thickness of the second adhesive layer 102 is about 3,000 angstroms (i.e., A) to 20,000 angstroms.

In some examples, the material of the first metal film layer includes, but is not limited to, copper (Cu), and the thickness of the first metal film layer is about 100 nm to 500 nm, and further may be about 50 nm to 35 m. In the following description, for example, the material of the first metal film layer is copper.

In some examples, to increase the adhesion of the first metal film layer to the glass substrate 10, an auxiliary metal film layer may be formed on the second surface of the glass substrate 10 by means including, but not limited to, magnetron sputtering, prior to forming the deposited first metal film layer. The auxiliary metal film layer is made of a material including but not limited to nickel (Ni), and the thickness of the auxiliary metal film layer is about 2 nm to 20 nm.

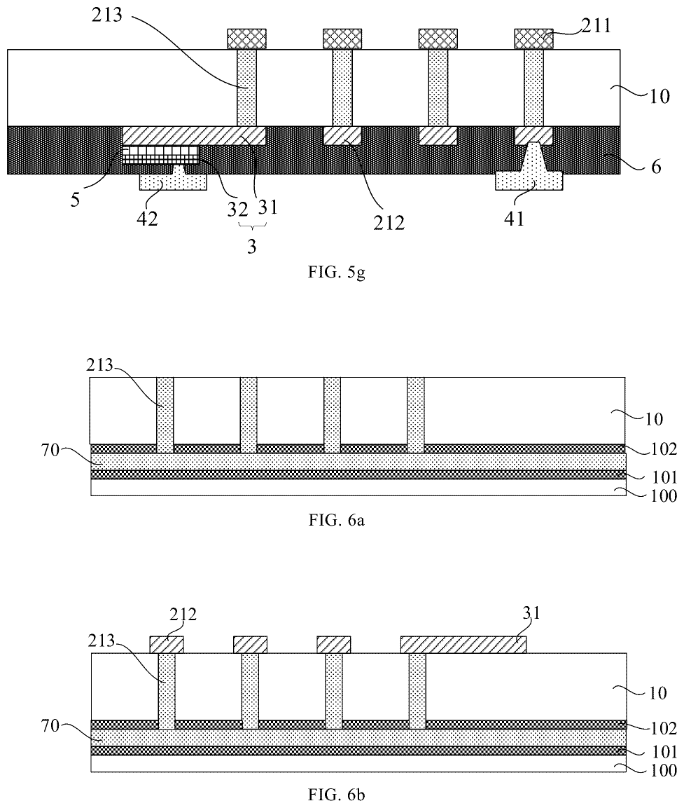

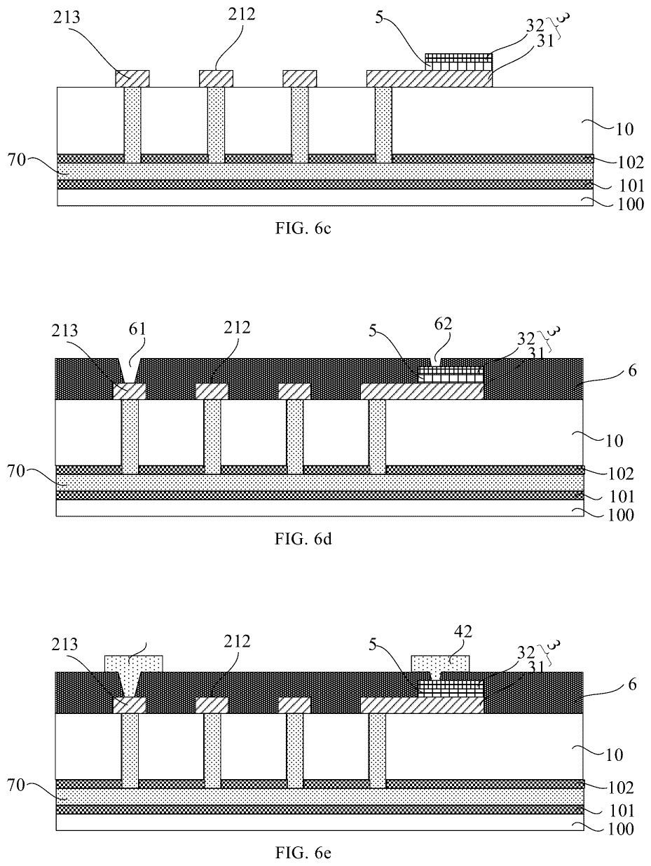

Step S23, attaching the first surface of the glass substrate 10 having therein the first connection vias 11 to the second adhesive layer 102, forming the first connection electrodes 213 in the first connection vias 11, respectively, through an electroplating process with the first metal film layer as a seed layer, as shown in FIG. 6a.

In some examples, similar to the foregoing step S13, step S23 may specifically include the following steps:

Electroplating and via-filling: putting the glass substrate 10 on a carrier of an electroplating machine, pressing on the power-on pad, putting the glass substrate into a via-filling electroplating bath (in which there is a special via-filling electrolyte), applying electric current, keeping the electroplating solution continuously and rapidly flowing on the surface of the glass substrate 10, such that cations in the electroplating solution obtain electrons on the inner wall of a first connection via 11 and deposit on the inner wall as atoms, wherein metal copper can be mainly deposited in the first connection via at a high speed (the deposition speed is 0.5 to 3 um/min), through the special via-filling electrolyte of special proportion. As time increases, the metal copper on the inner wall of the first connection via grows gradually thick, and even the first connection via 11 may be completely filled, that is, a corresponding first connection electrode 213 of the inductor coil is formed (that is, the spiral region of the inductor is manufactured). Finally, the glass substrate is taken out and subjected to a deionized water cleaning.

Step S24, forming a fourth metal film layer on the second surface of the glass substrate 10, and forming a pattern including the second sub-structures 212 of the inductor coil, the second lead terminal 23, and the first plate 31 of the capacitor 3, through a patterning process, as shown in FIG. 6b. The first end of the N-th first sub-structure 211 is connected to the second lead terminal 23 through one of the first connection vias 11, and the second lead terminal 23 is connected to the first plate 31 of the capacitor 3.

In some examples, in step S24, the fourth metal film layer is formed on the second surface of the glass substrate 10 by a method including, but not limited to, magnetron sputtering; then, coating photoresist thereon, exposing and developing the photoresist, and then carrying out a wet etching, stripping off the adhesive after the etching, thereby the pattern including the second sub-structures 212 of the inductor coil, the second lead terminal 23, and the first plate 31 of the capacitor 3 is formed. The material of the fourth metal film layer may be the same as that of the first metal film layer, and thus is not described herein again.

Step S25, forming a first interlayer dielectric layer 5 and the second plate 32 of the capacitor 3 on the glass substrate 10 formed with the second sub-structures 212 of the inductor coil, the second lead terminal 23, and the first plate 31 of the capacitor 3, as shown in FIG. 6c.

In some examples, step S25 may include sequentially forming the first interlayer dielectric layer 5 and a second metal film layer on the glass substrate 10 formed with the second sub-structures 212 of the inductor coil, the second lead terminal 23, and the first plate 31 of the capacitor 3; then, coating photoresist, exposing and developing the photoresist, and then carrying out a wet etching, stripping off the photoresist after the etching, thereby the pattern including the second plate 32 of the capacitor 3 is formed. Next, the first interlayer dielectric layer 5 may be further patterned to leave only a part of the first interlayer dielectric layer 5 under the second plate 32 of the capacitor 3.

In some examples, the material of the first interlayer dielectric layer 5 is an inorganic insulating material. For example, the first interlayer dielectric layer 5 is an inorganic insulating layer formed of silicon nitride (SiNₓ), or an inorganic insulating layer formed of silicon oxide (SiO₂), or a plurality of stacked composite film layers of a SiNₓ inorganic insulating layer and a SiO₂ inorganic insulating layer. Alternatively, the first interlayer dielectric layer 5 further serves as an interlayer dielectric layer of the capacitor 3.

In some examples, the material of the second metal film layer may be the same as the material of the first metal film layer, and thus is not described herein again.

Step S26, forming a second interlayer dielectric layer 6, and forming a second connection via 61 and a third connection via 62 penetrating through the second interlayer dielectric layer 6. The orthogonal projections of the second connection via 61 and the third connection via 62 on the glass substrate 10 respectively overlap with the orthogonal projections of the first lead terminal 22 and the second plate 32 on the glass substrate 10, as shown in FIG. 6d.

In some examples, the second interlayer dielectric layer 6 may be an inorganic insulating layer formed of silicon nitride (SiNₓ), or an inorganic insulating layer formed of silicon oxide (SiO₂), or a plurality of stacked composite film layers of a SiNₓ inorganic insulating layer and a SiO₂ inorganic insulating layer.

Step S27, forming a first connection pad 41 and a second connection pad 42 on the second interlayer dielectric layer 6; wherein the first connection pad 41 is connected to the first lead terminal 22 of the inductor coil through the second connection via 61; the second connection pad 42 is connected to the second plate 32 of the storage capacitor 3 through the third connection via 62, as shown in FIG. 6e.

In some examples, the first connection pad 41 and the second connection pad 42 may be specifically solder balls.

Step S28, turning over the glass substrate 10, peeling off the first metal film layer 70, the first adhesive layer 101, and the substrate 100, and forming a pattern including the first sub-structures 211 of the inductor coil on the first surface of the glass substrate 10 through a patterning process, as shown in FIG. 4.

In some examples, step S28 may include depositing a third metal film layer by magnetron sputtering, then, coating photoresist thereon, exposing and developing the photoresist, and then carrying out a wet etching, stripping off the photoresist after the etching, thereby the pattern including the first sub-structures 211 of the inductor coil is formed. The material of the third metal film layer may be the same as that of the first metal film layer, and thus, the description thereof is not repeated.

Thus, passive devices are integrated on the glass substrate 10 to form an LC oscillating circuit.

It should be noted that, in the embodiment of the present disclosure, the capacitance value of the capacitor 3 is determined by the thickness of the first interlayer dielectric layer 5, the dielectric constant of the material of the first interlayer dielectric layer 5, and the overlapping areas of the first plate 31 and the second plate 32. The inductance value is determined by the number of turns of the spiral line, the pitch of the spiral line and the diameter of the spiral line. Therefore, the dielectric constant of the material of the first interlayer dielectric layer 5 of the capacitor 3, the parameters of the first plate 31 and the second plate 32, the size, the distance and other parameters of the first sub-structures 211 and the second sub-structures 212 of the inductor coil may be reasonably designed, so that the effect of optimizing the LC oscillating circuit is achieved.

It will be understood that the above embodiments are merely exemplary embodiments adopted to illustrate the principles of the present disclosure, and the present disclosure is not limited thereto. It will be apparent to one of ordinary skill in the art that various modifications and improvements can be made without departing from the spirit and scope of the present disclosure, and such modifications and improvements are also considered to be within the scope of the present disclosure.

1. A manufacturing method of a substrate integrated with passive devices, comprising:
providing a transparent dielectric layer, wherein the transparent dielectric layer comprises a first surface and a second surface which are opposite to each other along a thickness direction of the transparent dielectric layer; and the transparent dielectric layer has first connection vias which penetrate through the transparent dielectric layer along the thickness direction of the transparent dielectric layer;
integrating the passive devices on the transparent dielectric layer, wherein forming the passive devices comprises at least forming an inductor; the inductor comprises first sub-structures on the first surface and second sub-structures on the second surface, and first connection electrodes in the first connection vias, respectively, to sequentially connect the first sub-structures and the second sub-structures together; wherein
the forming the inductor comprises:
forming a first metal film layer on the first surface and/or the second surface of the transparent dielectric layer, and forming the first connection electrodes in the first connection vias through an electroplating process; the first connection electrodes filling the first connection vias; and
forming a pattern comprising the first sub-structures on the first surface of the transparent dielectric layer through a patterning process, and forming a pattern comprising the second sub-structures on the second surface of the transparent dielectric layer through a patterning process.

2. The manufacturing method according to claim 1, wherein the forming the inductor comprises:
forming the first metal film layer on the second surface of the transparent dielectric layer, forming a first metal material in the first connection vias through a patterning process, and forming the first connection electrodes in the first connection vias through an electroplating process.

3. The manufacturing method according to claim 2, wherein prior to forming the first metal film layer on the second surface of the transparent dielectric layer, the manufacturing method further comprises:
forming an auxiliary metal film layer on the second surface of the transparent dielectric layer to increase an adhesive force between the first metal film layer and the second surface of the transparent dielectric layer.

4. The manufacturing method according claim 1, wherein the providing the transparent dielectric layer comprises:
providing a substrate, and coating a first adhesive layer on the substrate; and
attaching the first surface of the transparent dielectric layer to the first adhesive layer.

5. The manufacturing method according to claim 4, wherein a material of the first adhesive layer comprises a temperature-controlled adhesive.

6. The manufacturing method according to claim 1, wherein the forming the inductor comprises:
providing a substrate, and coating a first adhesive layer on the substrate;
forming a first metal film layer on the first adhesive layer;
forming a second adhesive layer on a side of the first metal film layer distal to the first adhesive layer, patterning the second adhesive layer to remove portions of the second adhesive layer corresponding to positions of the first connection vias in the transparent dielectric layer to be attached to the second adhesive layer; and
attaching the first surface of the transparent dielectric layer to the second adhesive layer, and forming the first connection electrodes in the first connection vias through an electroplating process.

7. The manufacturing method according to claim 6, wherein prior to forming the first metal film layer on the first adhesive layer, the manufacturing method comprises:
forming an auxiliary metal film layer on the first adhesive layer to increase an adhesive force between the first metal film layer and the first adhesive layer.

8. The manufacturing method according to claim 1, wherein the passive devices further comprise a capacitor, and the manufacturing method further comprises:
forming a first plate of the capacitor while forming the second sub-structures of the inductor;
forming a first interlayer dielectric layer on a side, which is distal to the transparent dielectric layer, of a layer where the second sub-structures of the inductor and the first plate of the capacitor are located; and
forming a second plate of the capacitor on a side of the first interlayer dielectric layer distal to the transparent dielectric layer.

9. The manufacturing method according to claim 8, wherein the inductor comprises a first lead terminal connected to a first connection pad and a second lead terminal connected to a second end of the first plate of the capacitor; the second plate of the capacitor is connected to a second connection pad; the manufacturing method further comprises:
forming a second interlayer dielectric layer on a side, which is distal to the first interlayer dielectric layer, of a layer where the second plate of the capacitor and the second connection pad are located;
forming a second connection via and a third connection via which penetrate through the second interlayer dielectric layer; and
forming the first connection pad and the second connection pad; wherein the first connection pad is connected to the first lead terminal through the second connection via; and the second connection pad is connected to the second plate of the capacitor through the third connection via.

10. The manufacturing method according to claim 1, wherein the transparent dielectric layer comprises a glass substrate.

11. A substrate integrated with passive devices, comprising a transparent dielectric layer and the passive devices integrated on the transparent dielectric layer; wherein
the transparent dielectric layer comprises a first surface and a second surface which are opposite to each other along a thickness direction of the transparent dielectric layer; and the transparent dielectric layer has first connection vias which penetrate through the transparent dielectric layer along the thickness direction of the transparent dielectric layer; and
the passive devices comprise at least an inductor; the inductor comprises first sub-structures on the first surface and second sub-structures on the second surface, and first connection electrodes in the first connection vias, respectively, to sequentially connect the first sub-structures and the second sub-structures together.

12. The substrate according to claim 11, wherein the passive devices further comprise a capacitor; the capacitor comprises a first plate which is in the same layer as the second sub-structures of the inductor; the substrate further comprises a first interlayer dielectric layer on a side, which is distal to the transparent dielectric layer, of the first plate of the capacitor; and the capacitor comprises a second plate on a side, which is distal to the first plate of the capacitor, of the first interlayer dielectric layer.

13. The substrate according to claim 11, wherein the transparent dielectric layer comprises a glass substrate.

14. The manufacturing method according to claim 2, wherein the passive devices further comprise a capacitor, and the manufacturing method further comprises:
forming a first plate of the capacitor while forming the second sub-structures of the inductor;
forming a first interlayer dielectric layer on a side, which is distal to the transparent dielectric layer, of a layer where the second sub-structures of the inductor and the first plate of the capacitor are located; and
forming a second plate of the capacitor on a side of the first interlayer dielectric layer distal to the transparent dielectric layer.

15. The manufacturing method according to claim 3, wherein the passive devices further comprise a capacitor, and the manufacturing method further comprises:
forming a first plate of the capacitor while forming the second sub-structures of the inductor;
forming a first interlayer dielectric layer on a side, which is distal to the transparent dielectric layer, of a layer where the second sub-structures of the inductor and the first plate of the capacitor are located; and
forming a second plate of the capacitor on a side of the first interlayer dielectric layer distal to the transparent dielectric layer.

16. The manufacturing method according to claim 4, wherein the passive devices further comprise a capacitor, and the manufacturing method further comprises:
forming a first plate of the capacitor while forming the second sub-structures of the inductor;
forming a first interlayer dielectric layer on a side, which is distal to the transparent dielectric layer, of a layer where the second sub-structures of the inductor and the first plate of the capacitor are located; and
forming a second plate of the capacitor on a side of the first interlayer dielectric layer distal to the transparent dielectric layer.

17. The manufacturing method according to claim 5, wherein the passive devices further comprise a capacitor, and the manufacturing method further comprises:
forming a first plate of the capacitor while forming the second sub-structures of the inductor;
forming a first interlayer dielectric layer on a side, which is distal to the transparent dielectric layer, of a layer where the second sub-structures of the inductor and the first plate of the capacitor are located; and
forming a second plate of the capacitor on a side of the first interlayer dielectric layer distal to the transparent dielectric layer.

18. The manufacturing method according to claim 6, wherein the passive devices further comprise a capacitor, and the manufacturing method further comprises:
forming a first plate of the capacitor while forming the second sub-structures of the inductor;
forming a first interlayer dielectric layer on a side, which is distal to the transparent dielectric layer, of a layer where the second sub-structures of the inductor and the first plate of the capacitor are located; and
forming a second plate of the capacitor on a side of the first interlayer dielectric layer distal to the transparent dielectric layer.

19. The manufacturing method according to claim 7, wherein the passive devices further comprise a capacitor, and the manufacturing method further comprises:
forming a first plate of the capacitor while forming the second sub-structures of the inductor;
forming a first interlayer dielectric layer on a side, which is distal to the transparent dielectric layer, of a layer where the second sub-structures of the inductor and the first plate of the capacitor are located; and
forming a second plate of the capacitor on a side of the first interlayer dielectric layer distal to the transparent dielectric layer.

20. The substrate according to claim 12, further comprising:
a second interlayer dielectric layer covering the second sub-structures and the capacitor;
a second connection via and a third connection via which penetrate through the second interlayer dielectric layer; and
a first connection pad and a second connection pad on the second interlayer dielectric layer and at positions of the second connection via and the third connection via, respectively;
wherein the inductor further comprises a first lead terminal connected to the first connection pad and a second lead terminal connected to the second connection pad.
